(19) United States
(12) Patent Application Publication
(10) Pub. No.: US 2017/0207177 A1
(43) Pub. Date: Jul. 20, 2017

(54) Quasi-Lateral Diffusion Transistor with Diagonal Current Flow Direction

(71) Applicant: Silanna Asia Pte Ltd., Ocean Financial Centre (SG)

(72) Inventors: Stuart B. Molin, Carlsbad, CA (US); George Imthurn, San Diego, CA (US)

(21) Appl. No.: 14/997,942

(22) Filed: Jan. 18, 2016

(51) Int. Cl. H01L 23/552; H01L 29/06; H01L 29/10; H01L 29/08; H01L 21/768; H01L 29/78; H01L 23/528; H01L 29/66; H01L 29/45

(52) U.S. Cl. CPC H01L 23/552; H01L 29/66681; H01L 29/0649; H01L 29/1095; H01L 29/45; H01L 21/76895; H01L 29/7816; H01L 23/528; H01L 29/0865; H01L 29/0882

(57) ABSTRACT

A quasi-lateral diffusion transistor is formed in a semiconductor-on-insulator (SOI) wafer by forming a gate region, a body region, a drift region, and a source region and bonding a handle wafer to the SOI wafer at a first side (e.g., top side) of the SOI wafer; and removing a semiconductor substrate of the SOI wafer, forming a hole in a buried insulator layer of the SOI wafer, and forming a drain region for the transistor at a second side (e.g., bottom side) of the SOI wafer. The body region and the drift region physically contact the buried insulator layer. The drain region is formed in a bottom portion of the drift region exposed by the hole and is laterally offset from the source region. In operation of the quasi-lateral diffusion transistor, a current flow direction through the semiconductor layer is diagonal between the source region and the drain region.

### BACKGROUND OF THE INVENTION

LDMOS (laterally diffused metal oxide semiconductor) transistors are commonly used in microwave/RF power amplifiers. In general, an LDMOS is an asymmetric power MOSFET designed for low on-resistance and high blocking voltage. These features are obtained by creating a diffused p-type channel region in a low-doped n-type drain region. The low doping on the drain side results in a large depletion layer with high blocking voltage. The channel region has a short channel with high current handling capability. A relatively deep p-type diffusion causes a large radius of curvature at the edges, which eliminates edge effects. While the device's name implies that the fabrication requires a diffusion, the dopants can just as well be implanted and annealed. Diffusion can be used in addition to further increase the junction depth and radius of curvature. The p-type body region is formed first, followed by p+ and n+ regions. The n+ regions provide both source and drain regions. The p+-region contacts the p-type body region, which is typically shorted to the source region, thereby eliminating the body effect.

A particular example prior art LDMOS structure 100 is shown in FIG. 1. The LDMOS structure 100 includes a source region 101, a body region 102, a drift region 103, a drain region 104, and a gate region 105. The gate region 105 is generally aligned with the top of the body region 102. A source terminal 106 connects through a source contact 107 to electrically connect to the source region 101. A drain terminal 108 connects through a drain contact 109 to electrically connect to the drain region 104. A gate shield 110 surrounds the gate region 105 within an insulating material 111 and electrically connects to the source region 101 and source contact 107. The LDMOS structure 100 is formed in and on a semiconductor-on-insulator (SOI) wafer 112 comprising a semiconductor substrate 113, a buried insulator layer 114, and a semiconductor layer 115. The active components (101-104) are formed in the semiconductor layer 115. An interconnect layer 116 (e.g., including various metallization layers, intervening insulation layers, and vias) electrically connect the source terminal 106 and the drain terminal 108 to various other electrical components in the overall integrated circuit (IC) die. The path of the current flow through the LDMOS structure 100 generally follows the dashed arrow 117. Since the source terminal 106 and the drain terminal 108 are both on the top side of the LDMOS structure 100, certain design rules for laterally spacing the terminals 106 and 108 apply so as to limit the minimum lateral/horizontal size, or pitch, of the LDMOS structure 100.

As with almost all electronic devices, improvement trends in the design, fabrication and performance of LDMOS devices generally seek greater or more efficient heat dissipation and electromagnetic interference (EMI) shielding capabilities, so that the LDMOS devices can operate faster, more efficiently and more reliably. Additionally, reductions in size for one or more physical dimensions of the structures that form the LDMOS devices are continuously sought after, so that the LDMOS devices can be packaged in ever smaller form factors.

### SUMMARY OF THE INVENTION

In some embodiments, fabrication of a quasi-lateral diffusion transistor in a semiconductor-on-insulator (SOI) wafer with improved heat dissipation, EMI shielding and size characteristics is achieved in a method in which forming a gate region, a body region, a drift region, and a source region for the transistor and bonding a handle wafer to the SOI wafer are performed at a first side (e.g., top side) of the SOI wafer; and removing a semiconductor substrate of the SOI wafer, forming a hole in a buried insulator layer of the SOI wafer, and forming a drain region for the transistor are performed at a second side (e.g., bottom side) of the SOI wafer. The gate region is formed on a semiconductor layer of the SOI wafer. The body region is formed in the semiconductor layer, physically contacts the buried insulator layer, and has a portion that is laterally aligned with the gate region. The drift region is formed in the semiconductor layer on a first side of the gate region and physically contacts the buried insulator layer. The source region is formed in the semiconductor layer on a second side of the gate region. The semiconductor substrate is removed to expose the buried insulator layer. The hole in the buried insulator layer is formed to expose the drift region. The hole is laterally offset from the source region on the first side of the gate region. The drain region is formed in the exposed drift region and is laterally offset from the source region on the first side of the gate region. In operation of the quasi-lateral diffusion transistor, a current flow direction through the semiconductor layer is diagonal between the source region and the drain region.

In some embodiments, a semiconductor structure having improved heat dissipation, EMI shielding and size characteristics is achieved in a quasi-lateral diffusion transistor comprising a body region, a gate region, a drift region, a source region, and a drain region formed in and on an SOI wafer with a handle wafer bonded at a top side of the SOI wafer. The SOI wafer has a buried insulator layer and a semiconductor layer on the top side of the buried insulator layer. The body region is formed in the semiconductor layer, extends from a top of the semiconductor layer to a bottom of the semiconductor layer, and physically contacts the buried insulator layer. The gate region is formed on the top of the semiconductor layer and is laterally aligned with a portion of the body region. The drift region is formed in the semiconductor layer on a first side of the gate region, extends from the top of the semiconductor layer to the bottom of the semiconductor layer, and physically contacts the buried insulator layer. The source region is formed in the top of the semiconductor layer on a second side of the gate region. The drain region is formed in the drift region in the bottom of the semiconductor layer on the first side of the gate region at a hole in the buried insulator layer laterally offset from the source region. In operation of the quasi-lateral diffusion transistor, a current flow direction through the semiconductor layer is diagonal between the source region and the drain region.

In some embodiments, the current flow direction has an angle between 8° and 23° from horizontal. In some embodiments, an electrical contact to the drain region is formed at the bottom side of the SOI wafer at the hole in the buried insulator layer with a material layer that laterally extends across a full lateral extent of the transistor below the transistor. In some embodiments, an electrical contact to the source region is formed at the top side of the SOI wafer with a second material layer that laterally extends across the full lateral extent of the transistor above the transistor. In some embodiments, a gate shield spaced above the gate region is formed at the top side of the semiconductor-on-insulator wafer, electrically connects to the source region and the body region, and laterally extends over the entire drift region. In some embodiments, the transistor has a source to drain lateral pitch of less than a micron.

### BRIEF DESCRIPTION OF THE DRAWINGS

FIG. 1 is a simplified cross sectional drawing of an example prior art LDMOS structure.

FIG. 2 is a simplified cross sectional drawing of an example quasi-lateral diffusion structure in accordance with an embodiment of the present invention.

FIG. 3 is a simplified flow chart of an example process for fabricating the example quasi-lateral diffusion structure shown in FIG. 2 in accordance with an embodiment of the present invention.

### DETAILED DESCRIPTION OF THE INVENTION

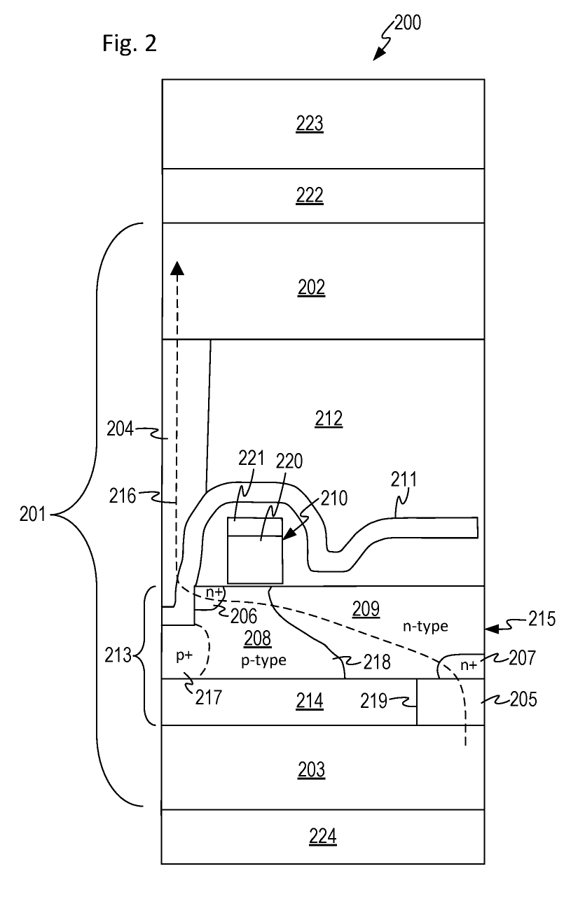

An example semiconductor structure 200, including a quasi-lateral diffusion transistor 201, having the improved heat dissipation, EMI shielding and size characteristics in accordance with an embodiment of the present invention, is shown in FIG. 2. The semiconductor structure 200 generally includes a source terminal 202, a drain terminal 203, a source contact 204, a drain contact 205, a source region 206, a drain region 207, a body or channel region 208, a drift region 209, a gate region 210, a gate shield 211, and an insulator layer 212, among other features for the quasi-lateral diffusion transistor 201 not shown for simplicity of illustration and description. The semiconductor structure 200 is generally formed in and on an SOI (semiconductor-on-insulator) wafer 213 having a semiconductor substrate (not shown), a buried insulator layer 214 on the semiconductor substrate, and a semiconductor layer 215 on the buried insulator layer 214.

The source region 206 is formed in or at the top side or surface of the semiconductor layer 215 on the left side (as shown) of the gate region 210. The drain region 207, on the other hand, is formed in or at the bottom side or surface of the semiconductor layer 215 on the right side (as shown) of the gate region 210. As a consequence of the locations of the source and drain regions 206 and 207, the current flow path through the semiconductor layer 215 is generally in the direction of arrow 216 diagonally (i.e., simultaneously lateral/horizontal and vertical) from the lower right drain region 207, through the drift region 209 and the body region 208, and to the upper left source region 206. The angle from horizontal of the current flow path between the source and drain regions 206 and 207, or through the semiconductor layer 215, is within a range between about 8° and about 23°, and more particularly between approximately 15°-20°. Thus, the quasi-lateral diffusion transistor 201 is referred to as a “quasi-lateral device,” i.e., neither an entirely lateral device nor a true vertical device. Additionally, the diagonal (i.e., horizontal and vertical offset) placement of the source and drain regions 206 and 207 enables formation of the features that result in the improved heat dissipation, EMI shielding and size characteristics, as described below.

In some embodiments, semiconductor processing steps (described below) are performed at the top side of the SOI wafer 213 to form the body region 208, the drift region 209, and the source region 206 in the semiconductor layer 215 and to form the gate region 210, the insulator layer 212, the gate shield 211, the source contact 204, and the source terminal 202 on the semiconductor layer 215. Additional semiconductor processing steps (described below) are performed at the bottom side of the SOI wafer 213 to form the drain region 207 in the semiconductor layer 215 and to form the drain contact 205 and the drain terminal 203 on the bottom side of the semiconductor layer 215 and/or the buried insulator layer 214. The relative position, orientation or direction terminology (e.g., top, bottom, above, below, front, back, over, under, horizontal, vertical, diagonal, etc.) is used in order to simplify the description of the semiconductor structure 200 and the formation thereof. The convention for the use of these terms is specified with respect to the relative orientation of elements in FIG. 2 and is maintained even when the semiconductor structure 200 is inverted for the bottom side processing.

In some embodiments, the body region 208 generally includes a semiconductor material with a p-type doping. In some embodiments, the body region 208 extends from a relatively narrow upper portion down to a wider lower portion that physically contacts the buried insulator layer 214. The body region 208, thus, has a relatively short channel with relatively high current handling capability. In some embodiments, the doping concentration is relatively constant throughout the body region 208. In other embodiments, the doping concentration has an intentional or inherent gradation, e.g., from a relatively high P+ doping in a left side deep well region 217 (i.e., a P+ doped, or heavily doped, region vertically aligned below the source region 206 and/or source contact 204 and approximately distinguished by a dashed line) to a relatively low P− doping in a right side p-type region 218 extending to the junction with the drift region 209.

In some embodiments, the drift region 209 generally includes a semiconductor material with a relatively low-doped n-type dopant for a large depletion layer with high blocking voltage and a relatively large cross section, large volume, and low resistance. In some embodiments, the drift region 209 extends from a relatively wide upper portion down to a narrower lower portion that physically contacts the buried insulator layer 214. Additionally, the drift region 209 is formed in physical contact with the body region 208 near the gate region 210 on the right side of the gate region 210.

In some embodiments, the source region 206 generally includes a semiconductor material with an n+-type doping. In some embodiments, the source region 206 is formed in physical contact with the body region 208 near the gate region 210 on the left side of the gate region 210.

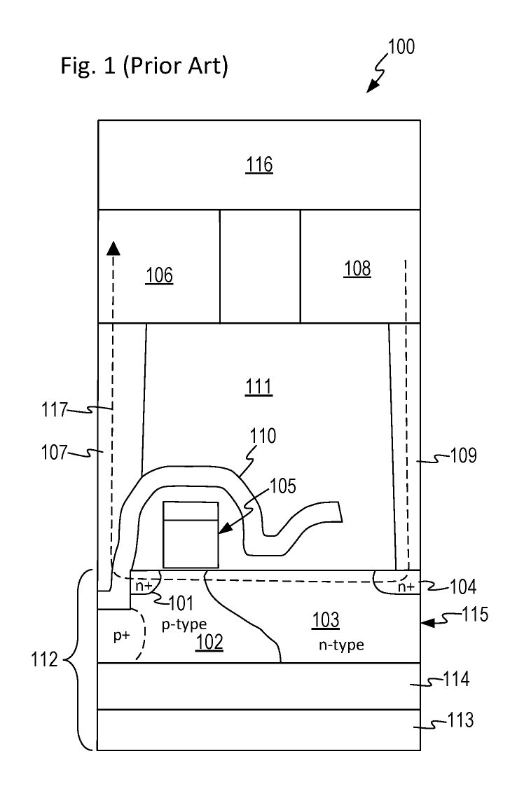

In some embodiments, the drain region 207 generally includes a semiconductor material with an n+-type doping. In some embodiments, the drain region 207 is formed at the desired location laterally and vertically offset from the source region 206 on the right side of the gate region 210. In order to achieve the placement of the drain region 207 in or at the bottom side or surface of the semiconductor layer 215, the semiconductor substrate (e.g., similar to the semiconductor substrate 113 of FIG. 1) of the SOI wafer 213 is removed, and a hole 219 is formed in the buried insulator layer 214, which is about 0.5 microns thick. The hole 219 exposes the semiconductor layer 215 (or the drift region 209) at the desired location laterally offset from the source region 206 on the right side of the gate region 210. The drain region 207 is thus formed by dopant ion implantation through the hole 219 into the bottom of the semiconductor layer 215 by bottom side processing steps, as described below.

In some embodiments, the gate region 210 further includes a doped polysilicon (or other conductive material) region 220, a gate insulator (disposed between the polysilicon region 220 and the semiconductor layer 215), and a gate metal (or other conductive material) contact 221. The gate region 210 is generally aligned with the narrow upper portion of the body region 208, but somewhat offset to the right (i.e., away from the source region 206) and slightly overlapping the drift region 209.

In some embodiments, the insulator layer 212 generally includes TEOS, silicon nitride, a silicon oxide, or other insulating material. In some embodiments, the insulator layer 212 is formed as more than one layer of material deposited at different times in order to surround the gate region 210 and the gate shield 211.

In some embodiments, the gate shield 211 generally includes a metal or other conductive material. In some embodiments, since the drain contact 205 is below the semiconductor layer 215, the gate shield 211 extends through the insulator layer 212 and over (spaced above) the gate region 210 and the drift region 209 into, and in some cases beyond, the region formerly occupied by the drain contact 109 (FIG. 1). In some embodiments, the gate shield 211 laterally extends over, and optionally beyond, the entire drift region 209. Additionally, the gate shield 211 is in physical and electrical contact with the body region 208 and the source region 206 and may be considered an extension of the source contact 204. In operation of the semiconductor structure 200, the gate shield 211 protects the gate region 210 from EMI, e.g., due to signals in the top interconnect layer 222.

In some embodiments, the source contact 204 generally includes a metal (e.g., tungsten, etc.) or other conductive material. The source contact 204 is in physical and electrical contact with the gate shield 211 and thus with the source region 206 and the deep well region 217.

In some embodiments, the source terminal 202 generally includes a metal or other conductive material in physical and electrical contact with the source contact 204. The source terminal 202 and the source contact 204 together form an electrical connection to the quasi-lateral diffusion transistor 201. Furthermore, since the drain terminal 203 is on the bottom of the semiconductor structure 200, rather than on the top, the source terminal 202 can have lateral dimensions that generally extend over all or a substantial portion of the insulator layer 212, or across a full lateral extent of the top side of the quasi-lateral diffusion transistor 201 or the semiconductor structure 200. In this manner, since the source terminal 202 covers a substantial portion of the quasi-lateral diffusion transistor 201 and includes a material having high thermal and electrical conductivity, it forms a heat spreader and/or an EMI shield on the top side of the quasi-lateral diffusion transistor 201. In some embodiments, the gate shield 211 and the top portion of the insulator layer 212 (i.e., a contact oxide between the source terminal 202 and the gate shield 211) are not included, such that the source terminal 202 is disposed directly on the bottom portion of the insulator layer 212 (i.e., a gate shield oxide between the gate shield 211 and the drift and gate regions 209 and 210). In this case, the source terminal 202 is close enough to the quasi-lateral diffusion transistor 201 to provide EMI shielding without the gate shield 211.

In some embodiments, a top interconnect layer 222 is formed above the quasi-lateral diffusion transistor 201. The top interconnect layer 222 generally includes, for example, contact and metallization layers with intervening dielectric/insulation material layers and conductive vias through the dielectric material layers. The top interconnect layer 222 provides top side electrical connections to the source terminal 202 and/or the body contact areas in order to electrically connect the quasi-lateral diffusion transistor 201 to various other semiconductor structures, passive and/or active electronic components, and/or external electrical connectors of the overall IC die.

In some embodiments, a handle wafer 223 is bonded to the top of the semiconductor structure 200 to form part of the semiconductor structure 200. The handle wafer 223 provides structural strength and stability to the overall structure for some of the processing steps, e.g., the semiconductor processing steps (described below) that are performed at the bottom side of the SOI wafer 213. The handle wafer 223 may be made of silicon (e.g., high resistivity Si), quartz, sapphire, AIN, SiC, an insulating material, etc. An additional heat spreading layer may optionally be placed between the handle wafer 223 and the rest of the semiconductor structure 200. In some embodiments, the handle wafer 223 includes various other semiconductor structures, passive and/or active electronic components, and/or external electrical connectors that may or may not electrically connect to the semiconductor structure 200. In other embodiments, the handle wafer 223 includes no such additional components. Some embodiments do not include a handle wafer in the final IC die. For example, the handle wafer 223 may be temporarily bonded to the semiconductor structure 200 for physical support during subsequent processing and then be removed when appropriate. For some embodiments, it may not be necessary to perform 314 if the SOI wafer 213 can be thinned or further processed, as described below, without needing the additional physical support of the handle wafer 223.

In some embodiments, the drain contact 205 generally includes a metal (e.g., tungsten, etc.) or other conductive material disposed in the hole 219 in the buried insulator layer 214. The drain contact 205 is in physical and electrical contact with the drain region 207.

In some embodiments, the drain terminal 203 generally includes a metal or other conductive material in physical and electrical contact with the drain contact 205. The drain terminal 203 and the drain contact 205 together form an electrical connection to the quasi-lateral diffusion transistor 201. Additionally, since the underlying semiconductor substrate of the SOI wafer 213 has been removed as described below, the drain terminal 203 is in physical contact with the buried insulator layer 214,. Furthermore, since the source and drain terminals 202 and 203 are on opposite sides of the quasi-lateral diffusion transistor 201, the drain terminal 203 can have lateral dimensions that generally extend under all or a substantial portion of the buried insulator layer 214, or across a full lateral extent of the bottom side of the quasi-lateral diffusion transistor 201 or the semiconductor structure 200. In this manner, since the drain terminal 203 underlays a substantial portion of the quasi-lateral diffusion transistor 201 and includes a material having high thermal and electrical conductivity, it forms a heat spreader and/or an EMI shield on the bottom side of the quasi-lateral diffusion transistor 201. Additionally, the removal of the semiconductor substrate of the SOI wafer 213 enables the drain terminal 203 to be relatively close to the semiconductor layer 215, and the material of the drain contact 205 has a high thermal conductivity, thereby further enhancing the heat dissipation characteristics.

In some embodiments, a bottom interconnect layer 224 is formed below the quasi-lateral diffusion transistor 201. The bottom interconnect layer 224 generally includes, for example, contact and metallization layers with intervening dielectric/insulation material layers and conductive vias through the dielectric material layers. The bottom interconnect layer 224 provides bottom side electrical connections to the drain terminal 203 in order to electrically connect the quasi-lateral diffusion transistor 201 to various other semiconductor structures, passive and/or active electronic components, and/or external electrical connectors of the overall IC die.

An advantage of the present design is that the EMI protection of the gate shield 211 and the source terminal 202 (or just of the source terminal 202 without the gate shield 211) is greater than that provided by the gate shield 110 in the design of FIG. 1, since the gate shield 211 and the source terminal 202 extend further than does the gate shield 110, and since the drain elements (203/205/207) are further away from the gate shield 211, the source terminal 202 and the gate region 210 compared to related elements in FIG. 1. Another advantage of the present design is that the EMI protection capabilities of the drain terminal 203 (due to the large lateral dimensions thereof) provide additional EMI shielding, thereby further enabling better performance and reliability of the Semiconductor structure 200. Another advantage of the present design is that the heat conductivity capability of the source terminal 202 and the drain terminal 203 (also due to the large lateral dimensions thereof) enable greater heat dissipation from, and thus better performance and reliability of, the semiconductor structure 200. A further advantage of the present design is that since the source terminal 202 and the drain terminal 203 are on opposite sides (top and bottom, respectively) of the semiconductor structure 200, the design rules for laterally spacing such terminals do not apply. Therefore, the minimum lateral/horizontal size, or pitch, of the semiconductor structure 200 is not limited by such design rules. Instead, the size or pitch of the semiconductor structure 200 is primarily limited by requirements for the lateral size of the drift region 209. Thus, the source to drain lateral size or pitch of the semiconductor structure 200 can be substantially smaller, e.g., less than a micron or on the order of 0.3-0.4 microns.

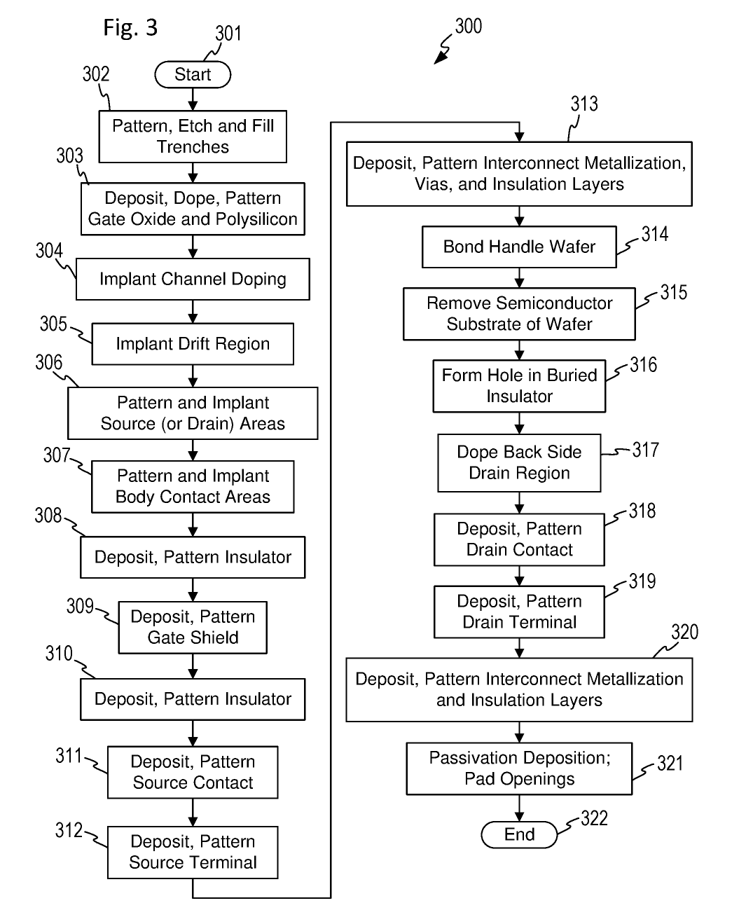

FIG. 3 shows an example process 300 for fabricating the Semiconductor structure 200 shown in FIG. 2, according to some embodiments of the present invention. It is understood, however, that the specific process 300 is shown for illustrative purposes only and that other embodiments (in addition to specifically mentioned alternative embodiments) may involve other processes or multiple processes with other individual steps or a different order or combination of steps and still be within the scope of the present invention.

The process 300 generally starts (at 301) with an SOI wafer having a semiconductor substrate, the buried insulator layer 214 on the semiconductor substrate, and the semiconductor layer 215 on the buried insulator layer 214. An acceptable SOI wafer for some embodiments preferably has a top silicon (Si) layer, e.g. about 0.2-1.0 pm to tens of microns in thickness.

At 302, various trench isolation regions (not shown) are patterned, etched and deposited/filled to isolate (as desired) the various devices (e.g., the quasi-lateral diffusion transistor 201) that are to be formed in the SOI wafer, in accordance with some embodiments. The trench isolation regions are formed by a trench etch or by a through-semiconductor via (TSV) etch to form relatively deep trenches or TSV structures followed by placement of an oxide/insulating material, as desired. In some embodiments, the trench isolation regions are formed down to (or almost down to, or at least down to) the buried insulator layer 214.

At 303, the gate region 210 is formed on the semiconductor layer 215 above and laterally aligned with a portion of the body region 208. In some embodiments, formation of the gate region 210 Includes depositing, doping and patterning the polysilicon (or other conductive material) region 220 overlaying a gate insulator (disposed between the polysilicon region 220 and the semiconductor layer 215) and depositing and patterning the gate metal contact 221.

At 304, the body or channel region 208 is patterned and implanted in the semiconductor layer 215 for appropriate channel doping, e.g. with a P-type dopant. Dopant diffusion and/or multiple implantations may be performed in order to achieve the gradation (mentioned above) if it is intentional. Alternatively, in some embodiments, 304 may be skipped if appropriate channel doping is present in the semiconductor layer 215 when the SOI wafer is manufactured.

At 305, the drift region 209 is patterned and implanted in the semiconductor layer 215 for appropriate low doped drain or drift doping, e.g. with an N-type dopant. In some embodiments, the doping concentration is relatively constant throughout the drift region 209. In other embodiments, the doping concentration has an intentional or inherent gradation throughout the drift region 209. Dopant diffusion and/or multiple implantations may be performed in order to achieve the gradation if it is intentional.

At 306, the source region 206 is patterned and implanted in the semiconductor layer 215 for appropriate source doping. For example, in some embodiments, an N+ dopant is implanted in the semiconductor layer 215 on the left side of the gate region 210.

At 307, body contact areas are patterned and implanted. For example, in some embodiments, a P+ dopant is implanted in exposed portions of body region 208 outside the plane of FIG. 2.

At 308, an initial lower portion (e.g., gate shield oxide) of the insulator layer 212 is deposited and patterned. For example, in some embodiments, a silicon dioxide material is deposited over and in physical contact with the gate region 210, the drift region 209 and the source region 206 in anticipation of placing the gate shield 211 thereon.

At 309, the gate shield 211 (if included) is deposited and patterned, e.g., a metal or other conductive material is deposited. Portions of the initial lower portion of the insulator layer 212 and of the semiconductor layer 215 may be removed at 309 to allow for proper placement of the gate shield 211 in physical and electrical contact with the body region 208 and the source region 206. In some embodiments, the gate shield 211 is formed over and in physical contact with the initial lower portion of the insulator layer 212 and extends over the drift region 209.

At 310, an upper portion (e.g., contact oxide) of the insulator layer 212 (if included) is deposited and patterned. For example, in some embodiments, an additional silicon dioxide material or other insulator is deposited over and around and in physical contact with the gate shield 211.

At 311, the source contact 204 is deposited and patterned. Portions of the upper portion of the insulator layer 212 may be removed at 311 to form a hole (e.g., a via, a trench, etc.) through the insulator layer 212 down to the gate shield 211. In some embodiments, a metal (e.g., tungsten, etc.) or other conductive material is thus deposited within the hole.

At 312, the source terminal 202 is deposited and patterned. In some embodiments, a metal or other conductive material is deposited over the insulator layer 212 and in physical and electrical contact with the source contact 204. In some embodiments, the source terminal 202 is formed extending over all or a substantial portion of the insulator layer 212, or across a full lateral extent of the quasi-lateral diffusion transistor 201 or the semiconductor structure 200.

At 313, the top interconnect layer 222 is deposited and patterned. For example, contact and metallization layers with intervening dielectric/insulation material layers and conductive vias through the dielectric material layers are formed for top side electrical connections for the quasi-lateral diffusion transistor 201 and the rest of the semiconductor structure 200.

At 314, the handle wafer 223 is bonded (e.g., by a low thermal resistivity fusion bond) to the exposed top surface of the SOI wafer to form a layer transferred bonded wafer structure. For embodiments that do not include a handle wafer in the final IC die, the handle wafer 223 may be temporarily bonded to the SOI wafer if the handle wafer 223 is needed for physical support of the SOI wafer during subsequent processing. In these approaches, the handle wafer 223 may be later removed when appropriate. For some embodiments, it may not be necessary to perform 314 if the SOI wafer can be thinned or further processed, as described below, without needing the additional physical support of the handle wafer 223.

At 315, an underlying portion of the original SOI wafer is preferably removed or thinned to expose the buried insulator layer 214. For example, the bonded wafer structure is inverted, and the semiconductor substrate under the buried insulator layer 214 is generally removed up to (and in some embodiments including portions of) the buried insulator layer 214. In this manner, the remaining wafer is generally left with only an insulation layer (e.g. the buried insulator layer 214 or a deposited insulator layer) underlying the semiconductor layer 215 and the trench isolation regions (formed at 302) at this point.

At 316, the hole 219 is formed through the buried insulator layer 214. For example, a portion of the buried insulator layer 214 is removed to expose the drift region 209 where the drain region 207 and the drain contact 205 will be formed laterally offset from the source region 206.

At 317, the drain region 207 is selectively doped at the back side of the bonded wafer structure, e.g. an N+ dopant is implanted through the hole 219 in the buried insulator layer 214 and into the bottom of the semiconductor layer 215 for appropriate drain doping. In some embodiments, the drain region 207 is thus formed in physical contact with the drift region 209 and laterally offset from, and substantially below, the source region 206 and the gate region 210 on the right side of the gate region 210. In some embodiments, if metals are present from the previous processing (e.g., at 311-313) that are tolerant only to low temperature processing, then the backside doping at 317 can be performed with an implant (which typically involves a low temperature) followed by dopant activation with a very short-time anneal, such as a laser or e-beam anneal.

At 318, the drain contact 205 is deposited and patterned. In some embodiments, a metal (e.g., tungsten, etc.) or other conductive material is thus deposited within the hole 219 in the buried insulator layer 214 and in physical and electrical contact with the drain region 207.

At 319, the drain terminal 203 is deposited and patterned. In some embodiments, a metal or other conductive material layer is deposited under (inverted) the buried insulator layer 214 and in physical and electrical contact with the drain contact 205. In some embodiments, the drain terminal 203 is formed extending under all or a substantial portion of the buried insulator layer 214, or at least across a full lateral extent of the quasi-lateral diffusion transistor 201 or the semiconductor structure 200, in order to form an additional heat spreader and/or electromagnetic interference shield on the bottom side of the quasi-lateral diffusion transistor 201.

At 320, the bottom interconnect layer 224 is deposited and patterned. For example, contact and metallization layers with intervening dielectric/insulation material layers and conductive vias through the dielectric material layers are formed for bottom side electrical connections to the drain terminal 203 in order to electrically connect the semiconductor structure 200 to various other semiconductor structures, passive and/or active electronic components, and/or external electrical connectors of the overall IC die.

At 321, various passivation deposition techniques are performed and pad openings are formed to generally complete the overall IC chip. The process 300 then preferably ends at 322.

Reference has been made in detail to embodiments of the disclosed invention, one or more examples of which have been illustrated in the accompanying drawings. Each example has been provided by way of explanation of the present technology, not as a limitation of the present technology. In fact, it will be apparent to those skilled in the art that modifications and variations can be made in the present technology without departing from the spirit and scope thereof. For instance, features illustrated or described as part of one embodiment may be used with another embodiment to yield a still further embodiment. Thus, it is intended that the present subject matter covers all such modifications and variations within the scope of the appended claims and their equivalents.

Although embodiments of the invention have been discussed primarily with respect to specific embodiments thereof, other variations are possible. Various configurations of the described structures or processes may be used in place of, or in addition to, the configurations presented herein.

Those skilled in the art will appreciate that the foregoing description is by way of example only, and is not intended to limit the invention, except where explicitly stated. Nothing in the disclosure should indicate that the invention is limited to systems that are implemented in a single circuit. Nothing in the disclosure should indicate that the invention is limited to systems that require a particular type of integrated circuit. Nothing in the disclosure should limit the invention to particular semiconductor devices, except where explicitly stated. In general, any diagrams presented are only intended to indicate one possible configuration, and many variations are possible. Those skilled in the art will also appreciate that methods and systems consistent with the present invention are suitable for use in a wide range of applications encompassing semiconductor devices and electronic circuits.

While the specification has been described in detail with respect to specific embodiments of the invention, it will be appreciated that those skilled in the art, upon attaining an understanding of the foregoing, may readily conceive of alterations to, variations of, and equivalents to these embodiments. These and other modifications and variations to the present invention may be practiced by those skilled in the art, without departing from the spirit and scope of the present invention, which is more particularly set forth in the appended claims.

1. A method comprising:
at a top side of a semiconductor-on-insulator wafer, the semiconductor-on-insulator wafer having a buried insulator layer with a top side and a bottom side opposite the top side, a semiconductor substrate on the bottom side of the buried insulator layer, and a semiconductor layer on the top side of the buried insulator layer:
forming a gate region for a quasi-lateral diffusion transistor on the semiconductor layer;
forming a body region for the quasi-lateral diffusion transistor in the semiconductor layer, the body region physically contacting the buried insulator layer, and a portion of the body region being laterally aligned with the gate region;
forming a drift region for the quasi-lateral diffusion transistor in the semiconductor layer on a first side of the gate region, the drift region physically contacting the buried insulator layer;
forming a source region for the quasi-lateral diffusion transistor in the semiconductor layer on a second side of the gate region; and
bonding a handle wafer to the semiconductor-on-insulator wafer; and
at a bottom side of the semiconductor-on-insulator wafer:
removing the semiconductor substrate to expose the buried insulator layer;
forming a hole in the buried insulator layer to expose the drift region, the hole being laterally offset from the source region on the first side of the gate region;
forming a drain region for the quasi-lateral diffusion transistor in the exposed drift region and laterally offset from the source region on the first side of the gate region; and
forming an electrical contact to the drain region for an external electrical connection to the quasi-lateral diffusion transistor at the hole in the buried insulator layer, the electrical contact including an electrically conductive material layer with an area that laterally extends across a full lateral extent of the quasi-lateral diffusion transistor below the quasi-lateral diffusion transistor and underlays all of the quasi-lateral diffusion transistor, the electrically conductive material layer of the electrical contact being in physical contact with a bottom side of the buried insulator layer across the full lateral extent of the quasi-lateral diffusion transistor and underlaying the buried insulator layer;
wherein, in operation of the quasi-lateral diffusion transistor, a current flow direction through the semiconductor layer is diagonal between the source region and the drain region.

2. The method of claim 1, wherein:
the current flow direction has an angle between 8° and 23° from horizontal.

3. (canceled)

4. The method of claim 1, further comprising:
at the top side of the semiconductor-on-insulator wafer:
forming an electrical contact to the source region for a second external electrical connection to the quasi-lateral diffusion transistor, the electrical contact to the source region including a second material layer that laterally extends across the full lateral extent of the quasi-lateral diffusion transistor above the quasi-lateral diffusion transistor.

5. The method of claim 1, further comprising:
at the top side of the semiconductor-on-insulator wafer:
forming a gate shield spaced above the gate region, electrically connected to the source region and the body region, and laterally extending over the entire drift region.

6. The method of claim 1, further comprising:
at the top side of the semiconductor-on-insulator wafer:
forming a top side source contact spaced above the gate region, electrically connected to the source region, and laterally extending over the entire drift region.

7. The method of claim 1, further comprising:
at the top side of the semiconductor-on-insulator wafer:
forming a top side source contact in electrical contact with the source region;
wherein the body region has a P+ doped deep well region aligned below and in electrical contact with the top side source contact.

8. The method of claim 1, further comprising:
at the top side of the semiconductor-on-insulator wafer:
before bonding the handle wafer to the semiconductor-on-insulator wafer, forming an interconnect layer that electrically connects to the source region.

9. The method of claim 1, further comprising:
at the bottom side of the semiconductor-on-insulator wafer:
forming an interconnect layer that electrically connects to the drain region through the hole in the buried insulator layer.

10. The method of claim 1, wherein:
the quasi-lateral diffusion transistor has a source to drain lateral pitch of less than a micron.

11. A method comprising:
at a first side of a semiconductor-on-insulator wafer, the semiconductor-on-insulator wafer having a buried insulator layer, a semiconductor layer on a first side of the buried insulator layer, and a semiconductor substrate on a second side of the buried insulator layer:
forming a gate region for a quasi-lateral diffusion transistor on the semiconductor layer;
forming a body region for the quasi-lateral diffusion transistor in the semiconductor layer, the body region physically contacting the buried insulator layer, and a portion of the body region being laterally aligned with the gate region;
forming a drift region for the quasi-lateral diffusion transistor in the semiconductor layer on a first side of the gate region, the drift region physically contacting the buried insulator layer;
forming a source region for the quasi-lateral diffusion transistor in the semiconductor layer on a second side of the gate region; and
bonding a handle wafer to the semiconductor-on-insulator wafer; and
at a second side of the semiconductor-on-insulator wafer:
removing the semiconductor substrate to expose the buried insulator layer;
forming a hole in the buried insulator layer to expose the drift region, the hole being laterally offset from the source region on the first side of the gate region;
forming a drain region for the quasi-lateral diffusion transistor in the exposed drift region and laterally offset from the source region on the first side of the gate region; and
forming an electrical contact to the drain region for an external electrical connection to the quasi-lateral diffusion transistor at the hole in the buried insulator layer, the electrical contact including an electrically conductive material layer with an area that laterally extends across a full lateral extent of the quasi-lateral diffusion transistor below the quasi-lateral diffusion transistor and underlays all of the quasi-lateral diffusion transistor, the electrically conductive material layer of the electrical contact being in physical contact with a bottom side of the buried insulator layer across the full lateral extent of the quasi-lateral diffusion transistor and underlaying the buried insulator layer;
wherein, in operation of the quasi-lateral diffusion transistor, a current flow direction through the semiconductor layer is diagonal between the source region and the drain region.

12. A semiconductor structure comprising:
a body region for a quasi-lateral diffusion transistor, the body region being formed in a semiconductor layer of a semiconductor-on-insulator wafer, the semiconductor-on-insulator wafer having a buried insulator layer with a top side and a bottom side opposite the top side, the semiconductor layer being on the top side of the buried insulator layer, the body region extending from a top of the semiconductor layer to a bottom of the semiconductor layer, and the body region physically contacting the buried insulator layer;
a gate region for the quasi-lateral diffusion transistor, the gate region being formed on the top of the semiconductor layer, and the gate region being laterally aligned with a portion of the body region;
a drift region for the quasi-lateral diffusion transistor, the drift region being formed in the semiconductor layer on a first side of the gate region, the drift region extending from the top of the semiconductor layer to the bottom of the semiconductor layer, and the drift region physically contacting the buried insulator layer;
a source region for the quasi-lateral diffusion transistor, the source region being formed in the top of the semiconductor layer on a second side of the gate region;
a handle wafer bonded at a top side of the semiconductor-on-insulator wafer;
a drain region for the quasi-lateral diffusion transistor, the drain region being formed in the drift region in the bottom of the semiconductor layer on the first side of the gate region at a hole in the buried insulator layer laterally offset from the source region; and
an electrical contact to the drain region formed at the bottom side of the semiconductor-on-insulator wafer for an external electrical connection to the quasi-lateral diffusion transistor at the hole in the buried insulator layer, the electrical contact including a material layer with an area that laterally extends across a full lateral extent of the quasi-lateral diffusion transistor below the quasi-lateral diffusion transistor and underlays all of the quasi-lateral diffusion transistor;
wherein, in operation of the quasi-lateral diffusion transistor, a current flow direction through the semiconductor layer is diagonal between the source region and the drain region.

13. The semiconductor structure of claim 12, wherein:
the current flow direction has an angle between 8° and 23° from horizontal.

14. (canceled)

15. The semiconductor structure of claim 14, further comprising:
an electrical contact to the source region formed at the top side of the semiconductor-on-insulator wafer for a second external electrical connection to the quasi-lateral diffusion transistor, the electrical contact to the source region including a second material layer that laterally extends across the full lateral extent of the quasi-lateral diffusion transistor above the quasi-lateral diffusion transistor.

16. The semiconductor structure of claim 12, further comprising:
a gate shield spaced above the gate region, electrically connected to the source region and the body region, and laterally extending over the entire drift region.

17. The semiconductor structure of claim 12, further comprising:
a top side source contact spaced above the gate region, electrically connected to the source region, and laterally extending over the entire drift region.

18. The semiconductor structure of claim 12, further comprising:
a top side source contact in electrical contact with the source region;
wherein the body region has a P+ doped deep well region aligned below and in electrical contact with the top side source contact.

19. The semiconductor structure of claim 12, further comprising:
an interconnect layer that electrically connects to the drain region through the hole in the buried insulator layer and is disposed on an opposite side of the semiconductor layer from the handle wafer.

20. The semiconductor structure of claim 12, wherein:
the quasi-lateral diffusion transistor has a source to drain lateral pitch of less than a micron.
